(19) United States
(12) Patent Application Publication
(10) Pub. No.: US 2024/0131819 A1
(43) Pub. Date: Apr. 25, 2024

(54) THERMALLY CONDUCTIVE BOARD

(71) Applicant: Polytronics Technology Corp., Hsinchu (TW)

(72) Inventors: KAI-WEI LO, Zhubei City (TW); WEN-FENG LEE, Taoyuan City (TW); HSIANG-YUN YANG, Zhudong Township (TW); KUO-HSUN CHEN, Toufen City (TW)

(21) Appl. No.: 18/312,135

(22) Filed: May 3, 2023

(30) Foreign Application Priority Data
Oct. 23, 2022 (TW) 111140178

(51) Int. Cl. B32B 15/08; B32B 3/02; B32B 15/20; B32B 33/00

(52) U.S. Cl. CPC B32B 15/08; B32B 3/02; B32B 15/20; B32B 33/00; B32B 2250/03; B32B 2250/40; B32B 2305/30; B32B 2307/206; B32B 2307/302; B32B 2307/538; B32B 2311/12

(57) ABSTRACT

A thermally conductive board includes a first metal layer, a second metal layer, and a thermally conductive layer. The material of the first metal layer includes copper, and the first metal layer has a first top surface and a first bottom surface opposite to the first top surface. A first metal coating layer covers the first bottom surface. The material of the second metal layer includes copper, and the second metal layer has a second top surface and a second bottom surface opposite to the second top surface. A second metal coating layer covers the second top surface and faces the first metal coating layer. The thermally conductive layer is an electrically insulator laminated between the first metal coating layer and the second metal coating layer.

### BACKGROUND OF THE INVENTION

### (1) Field of the Invention

The present application relates to a thermally conductive board, and more specifically, to a thermally conductive board having a thick copper layer.

### (2) Description of the Related Art

As technology develops, electronic devices for high power or high current application (e.g., in the field of electric car, internet of things, high performance computing, or the like) become common and are needed to meet the requirements in the future. Therefore, the wiring layer in the circuit board must be thicker enough to withstand high power or high current. For example, insulated gate bipolar transistor (IGBT) is one of the most used semiconductor devices in the high power module. During operation, such IGBT high power module allows a large amount of current to flow in the circuit, and thus a thicker wiring layer (i.e., thick copper layer) is used in the circuit board so as to withstand high current and increase dissipation of heat. The general formula of thermal conductivity is k=(Q/t)*L/(A*ΔT). “k” is thermal conductivity (W/mk); “Q” is heat (W); “t” is time; “L” is length (m); “A” is area of cross section (m²); and “ΔT” is temperature. Thermal conductivity determines the quantity of heat which flows in unit time. The length may correspond to the thickness of the wiring layer, and there is a positive correlation between the thickness and thermal conductivity. It is clear that thicker copper layer not only provides more current but also enhances heat dissipation.

Conventionally, single or multiple layers of thermally conductive but electrically insulating material (referred to as “thermally conductive layer” hereinafter for simplification) may be further provided underneath the wiring layer, thereby enhancing heat dissipation from the high power module. Taking conventional direct bonded copper (DBC) substrate as an example, the thick copper layer is bonded to a ceramic substrate by the sintering process. The ceramic substrate is an electrically insulating substrate which is excellent in thermal conduction, and the thick copper layer is used to form the wiring layer for electrical connection. However, in this type of substrate, adhesion between the thick copper layer and the thermally conductive layer needs improvement, and it has poor performance, especially when operated under extreme conditions. For example, in thermal shock test, there is an issue such as delamination or peeling between the thick copper layer and the thermally conductive layer; and in high temperature high humidity bias test (HHBT), the issue of migration of copper ions arises besides the aforementioned delamination or peeling, thereby compromising the electrical insulation of the thermally conductive layer, and the voltage endurance and other physical/chemical properties thereof are also adversely affected.

Obviously, there is a need to solve the problems existing in conventional thermally conductive boards, such as, peeling and poor performance in HHBT.

### SUMMARY OF THE INVENTION

The present invention provides a thermally conductive board having double-sided copper-containing metal layers (i.e., “first metal layer” and “second metal layer”) and a thermally conductive layer laminated therebetween. The surface of the first metal layer and the surface of the second metal layer are covered by a first metal coating layer and a second metal coating layer, respectively. In this way, the adhesion strength (i.e., peel strength) between the metal layers and the thermally conductive layer is increased; and migration of copper ions is prevented and other properties with regard to chemical inertness are enhanced. Because of the increase in adhesion strength and chemical inertness, the integrity of entire structure of the thermally conductive board is further maintained, thereby improving reliability. In other words, the operating endurance of the thermally conductive board (i.e., its service time) can be significantly prolonged during practical use.

In accordance with an aspect of the present invention, a thermally conductive board includes a first metal layer, a second metal layer, and a thermally conductive layer. The first metal layer includes copper, and has a first top surface and a first bottom surface opposite to the first top surface, wherein a first metal coating layer covers the first bottom surface. The second metal layer includes copper, and has a second top surface and a second bottom surface opposite to the second top surface, wherein a second metal coating layer covers the second top surface and faces the first metal coating layer. The thermally conductive layer is electrically insulative, and is laminated between the first metal coating layer and the second metal coating layer.

In an embodiment, the first metal coating layer has a thickness not greater than 50 μm.

In an embodiment, the thickness of the first metal coating layer ranges from 1 μm to 10 μm.

In an embodiment, the second metal coating layer has a thickness ranging from 1 μm to 10 μm.

In an embodiment, the first bottom surface of the first metal layer is a coarse surface after physical roughening.

In an embodiment, the first metal coating layer forms a plurality of bulges on the coarse.

In an embodiment, each bulge of the first metal coating layer has a microstructure feature, and the microstructure feature is globular, polyhedral, needle-like, or irregularly shaped, thereby forming a surface morphology.

In an embodiment, the first metal coating layer has a roughness (Ra) ranging from 0.15 μm to 0.60 μm.

In an embodiment, an adhesion strength between the first metal layer and the thermally conductive layer ranges from 0.5 Kg/cm to 3.0 Kg/cm.

In an embodiment, the second top surface of the second metal layer is a coarse surface after physical roughening, and the second metal coating layer forms a plurality of bulges on the coarse surface, wherein the second metal coating layer has a roughness (Ra) ranging from 0.15 μm to 0.60 μm.

In an embodiment, each bulge of the second metal coating layer has a microstructure feature, and the microstructure feature is globular, polyhedral, needle-like, or irregularly shaped, thereby forming a surface morphology.

In an embodiment, an adhesion strength between the second metal layer and the thermally conductive layer ranges from 0.5 Kg/cm to 3.0 Kg/cm.

In an embodiment, the first metal coating layer and the second metal coating layer are each independently made of a material selected from the group consisting of nickel, tin, zinc, chromium, bismuth, cobalt, and any combination thereof.

In an embodiment, the thermally conductive board further includes a bridging layer. The bridging layer is laminated between the first metal coating layer and the thermally conductive layer.

In an embodiment, the bridging layer includes at least one bridging compound selected from the group consisting of organic metal chelating agent, organic silane coupling agent, siloxane resin, epoxy resin, and any combination thereof.

In an embodiment, the first metal layer and the second metal layer are made of copper.

In an embodiment, the first metal layer has a thickness ranging from 0.1 mm to 10 mm.

In an embodiment, the thermally conductive layer includes a polymer matrix and a heat conductive filler, and the heat conductive filler has a heat conductivity ranging from 3 W/mK to 20 W/mK.

In an embodiment, the polymer matrix has a thermoset resin, and the heat conductive filler has a thermally conductive ceramic material selected from the group consisting of zirconium nitride, boron nitride, aluminum nitride, silicon nitride, aluminum oxide, magnesium oxide, zinc oxide, silicon dioxide, titanium dioxide, and any combination thereof.

### BRIEF DESCRIPTION OF THE DRAWINGS

The present application will be described according to the appended drawings in which:

FIG. 1 shows a cross-sectional view of a thermally conductive board in accordance with an embodiment of the present invention;

FIG. 2 shows an enlarged view of a part of the thermally conductive board shown in FIG. 1;

FIG. 3 shows an alternative embodiment in accordance with the enlarged view of the thermally conductive board shown in FIG. 2; and

FIG. 4 shows a schematic view of the bridging mechanism offered by a bridging layer.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

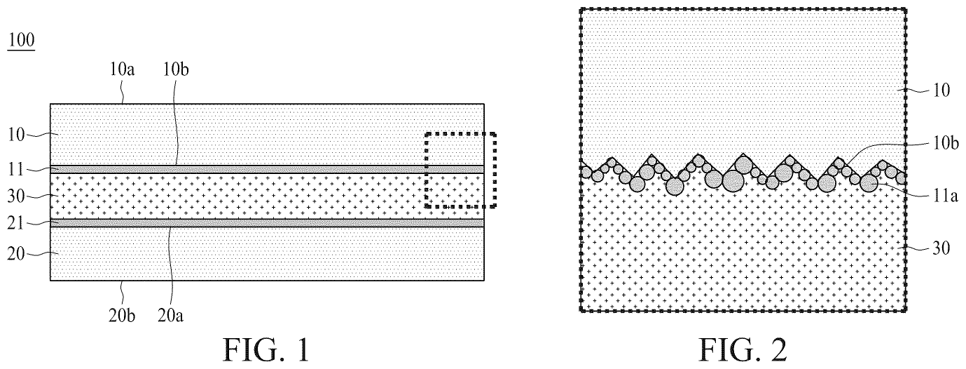

Please refer to FIG. 1. FIG. 1 shows one basic aspect of a thermally conductive board 100 of the present invention in cross-sectional view. The thermally conductive board 100 includes a first metal layer 10, a second metal layer 20, and a thermally conductive layer 30. The first metal layer 10 includes copper, and has a first top surface 10a and a first bottom surface 10b opposite to each other, wherein a first metal coating layer 11 covers the first bottom surface 10b. The second metal layer 20 includes copper, and has a second top surface 20a and a second bottom surface opposite to each other, wherein a second metal coating layer 21 covers the second top surface 20a and faces the first metal coating layer 11. The thermally conductive layer 30 is electrically insulative, and is laminated between the first metal coating layer 11 and the second metal coating layer 21. More specifically, the first metal layer 10 and the second metal layer 20 are both copper-containing metal layers and electrically conductive. The first metal layer 10, the second metal layer 20, and the thermally conductive layer 30 may form a triple-layer structure of the thermally conductive board 100 by hot pressing. Because of the thermally conductive layer 30, the first metal layer 10 is electrically isolated from the second metal layer 20. Subsequently, the first metal layer 10 and/or the second metal layer 20 can be processed to form the wiring layers to be assembled with various electronic components. Besides the wiring layers, the thermally conductive layer 30 is excellent in heat conduction, and therefore heat produced from the electronic components can be effectively transferred from the thermally conductive layer 30 to any metal layer for heat dissipation. In an embodiment, the thermally conductive layer 30 includes a polymer matrix and a heat conductive filler, and the heat conductive filler has a heat conductivity ranging from 3 W/mK to 20 W/mK. The polymer matrix has a thermoset resin, and the heat conductive filler has a thermally conductive ceramic material. The thermally conductive ceramic material may be selected from the group consisting of zirconium nitride, boron nitride, aluminum nitride, silicon nitride, aluminum oxide, magnesium oxide, zinc oxide, silicon dioxide, titanium dioxide, and any combination thereof.

In the present invention, the surface structure of both the first metal layer 10 and the second metal layer 20 are modified in order to prolong the lifetime of the thermally conductive board 100. As described above, the first bottom surface 10b of the first metal layer 10 and the second top surface 20a of the second metal layer 20 are covered by the first metal coating layer 11 and the second metal coating layer 21, respectively. That is, before the first metal layer 10, the second metal layer 20, and the thermally conductive layer 30 are hot-pressed, the first bottom surface 10b of the first metal layer 10 can be plated with the first metal coating layer 11 and the second top surface 20a of the second metal layer 20 can be plated with the second metal coating layer 21. With the first metal coating layer 11 and the second metal coating layer 21 being plated, the adhesion strength between the electrically conductive metal layer and the electrically insulating layer (i.e., the first metal layer 10 and the thermally conductive layer 30, or the second metal layer 20 and the thermally conductive layer 30) can be increased, and the electrically conductive metal layer is offered better chemical inertness in the meantime. For example, one benefit of the aforementioned chemical inertness is prevention of migration of copper ions. The first metal coating layer 11 acts as a barrier layer so that copper ions cannot penetrate the first metal coating layer 11 and migrate from the first metal layer 10 to the thermally conductive layer 30 when a bias voltage is applied. The second metal coating layer 21 has the same technical effect as the first metal coating layer 11. According to the verification result, the first metal coating layer 11 (or the second metal coating layer 21) may have a thickness not greater than 50 μm, and the thickness preferably ranges from 1 μm to 10 μm. If the thickness of the first metal coating layer 11 (or the second metal coating layer 21) is lower than 1 μm, the adhesion strength between the first metal layer 10 (or the second metal layer 20) and the thermally conductive layer 30 is too low, and the thermally conductive board 100 cannot endure for a long period of hours, such as 100 hours below, in HHBT. If the thickness of the first metal coating layer 11 (or the second metal coating layer 21) is increased to 10 μm, the adhesion strength between the first metal layer 10 (or the second metal layer 20) and the thermally conductive layer 30 is optimal, and the endurable time duration of the thermally conductive board 100 in HHBT can be extended to reach up to 3000 hours. If the thickness is further increased to a certain level (e.g., from 10 μm to 50 μm), the adhesion strength between the first metal layer 10 (or the second metal layer 20) and the thermally conductive layer 30 is almost the same, and so is the endurable time duration in HHBT.

Please refer to FIG. 2, which further shows an enlarged view of the dashed square in FIG. 1. As shown in FIG. 2, the first bottom surface 10b of the first metal layer 10 is a coarse surface after physical roughening, and the first metal coating layer 11 forms a plurality of bulges 11a on the coarse surface. More specifically, in order to increase the adhesion between the first metal layer 10 and the thermally conductive layer 30, the first bottom surface 10b of the first metal layer 10 is physically roughened to form the coarse surface. Because of the uneven property of the coarse surface, the contact area between the first metal layer 10 and the thermally conductive layer 30 is increased, thereby enhancing the effect of mechanical interlocking. The thermally conductive layer 30 can be adhered to the first metal layer 10 more tightly by hot pressing. Moreover, in the present invention, the first bottom surface 10b is plated with the first metal coating layer 11, and the first metal coating layer 11 conformally forms on the uneven first bottom surface 10b. It is noted that, from the technical point of view, the metal plating process is actually a metal crystallization process, and therefore the bulges 11a of the first metal coating layer 11 are conformally formed on the first bottom surface 10b and are formed in different sizes through crystallization. Besides the coarse surface, the size variety of the bulges 11a may further enhance the effect of mechanical interlocking. On the other hand, the size variety of bulges 11a may also make up for deficiencies of the roughening process in case that the first bottom surface 10b is not rough enough to form the coarse surface. Furthermore, from the micro perspective, each bulge 11a of the first metal coating layer 11 has at least one microstructure feature therein. The microstructure feature is substantially the crystalline structure. If one single bulge 11a (which is schematically illustrated as a globe in FIG. 2) is observed in a zoom-in view, the microstructure feature (not shown) in such globular bulge 11a may be globular, polyhedral, needle-like, or irregularly shaped. In other words, the bulge 11a may consist of the microstructure features which have the shapes as described above. These microstructure features make the surface more uneven (i.e., the surface morphology becomes more uneven), and are favorable to increase the adhesion strength ranging from 0.5 Kg/cm to 3.0 Kg/cm. In an embodiment, the first metal coating layer 11 has a thickness ranging from 1 μm to 50 μm, and has a roughness (Ra) ranging from 0.15 μm to 0.60 μm. For example, the thickness of the first metal coating layer 11 may range from 1 μm to 10 μm, and its roughness (Ra) may range from 0.38 μm to 0.52 μm. In another embodiment, the thickness of the first metal coating layer 11 may range from 10 μm to 50 μm, and its roughness (Ra) may be 0.52 μm. Since the thickness and the roughness (Ra) of the first metal coating layer 11 are properly controlled, the adhesion strength is larger than 0.8 Kg/cm as required by the Institute of Printed Circuit (IPC). Likewise, the second metal coating layer 21 may have a thickness and a roughness (Ra) the same as the first metal coating layer 11 as described above.

It is understood that the globular shape of the bulges 11a in FIG. 2 is illustrative only, any bulge shape can be included in the scope of the present invention. The first bottom surface 10b is substantially the coarse surface due to physical roughening as described above. Likewise, although the coarse surface is illustrated by a zigzag line, its surface morphology is not limited thereto. The coarse surface may be a wavy, irregular, or any uneven surface. As for second metal layer 20, the second top surface 20a of the second metal layer 20 may be the coarse surface the same as the first bottom surface 10b of the first metal layer 10. The second metal coating layer 21 may have a bulge 11a and a microstructure feature of the bulge 11a the same as that of the first metal coating layer 11. In an embodiment, the first metal coating layer 11 and the second metal coating layer 21 are each independently made of a material selected from the group consisting of nickel, tin, zinc, chromium, bismuth, cobalt, and any combination thereof.

In order to apply the thermally conductive board 100 to the high power module, the first metal layer 10 and the second metal layer 20 are made of copper, and especially are thick copper plates, each of which has a thickness ranging from 0.1 mm to 10 mm. In an embodiment, the thick copper plate can be plated with nickel to obtain a nickel coating layer. It is understood that ounce (oz) is often used to describe the thickness of the copper plate in the industry of Thermally Conductive Board (TCB), Printed Circuit Board (PCB), or other similar boards. 1 oz is equal to about 0.035 mm. Conventionally, a copper foil (or copper plate) does not include a nickel-plated layer in case its thickness is more than 3 oz. This is because the thinner thickness (i.e., less than 3 oz) allows the copper foil to be able to be easily scrolled or winded in the process, while the thicker thickness does not. For example, a winding apparatus is provided with two ends (i.e., an input end and output end), each of which has a roller, and such roller may act as an axis for winding the copper foil. The copper foil is disposed on the winding apparatus across from the input end to the output end; and opposite ends of the copper foil are winded on the roller at the input end and on the roller at the output end, respectively. Both rollers rotate at the same direction, and thus the copper foil can be rolled out from the input end and winded up at the output end. During the rotation as described above, the copper foil between the input end and output end can be rotated into a plating tank, and then winded up at the output end after plating. In this way, the plated copper foil may be directly rolled into a cylindrical form at the output end for convenience of packaging and transportation. However, once the copper plate has a thick thickness greater than 3 oz, the copper plate easily breaks or has other physical damages during the rotation, and therefore the thick copper plate cannot be bent during plating (such plating process for thick copper plate is referred to as “plate plating process” hereinafter for simplification). It is noted that the plate plating process requires higher equipment costs. And, if any similar process is subsequently needed, any additional apparatus for the similar process is correspondingly required to be a “non-winding” apparatus. From the above, the nickel plating process on the thick copper plate not only needs higher equipment costs, but also increases difficulty in subsequent process design. The present invention plates two thick copper plate (the first metal layer 10 and the second metal layer 20) with nickel so that the adhesion strength on both sides of the thermally conductive layer 30 and the chemical inertness (e.g., prevention of copper ion migration) of both copper plates are increased. In other words, the present invention adopts a nickel-plated and thick-copper double layer, which is not conventionally used due to higher costs and difficulty in process design described above, and further increases the adhesion strength and chemical inertness, thereby improving the endurance of the thermally conductive board 100 in practical use. In an embodiment, the thickness of a single copper plate may range from 0.3 mm to 8.3 mm, such as 0.3 mm, 1.3 mm, 2.3 mm, 3.3 mm, 4.3 mm, 5.3 mm, 6.3 mm, 7.3 mm, or 8.3 mm. In another embodiment, considering formation of the wiring layer subsequently, the thickness of a single copper plate may preferably range from 1 mm to 4 mm for convenience purpose.

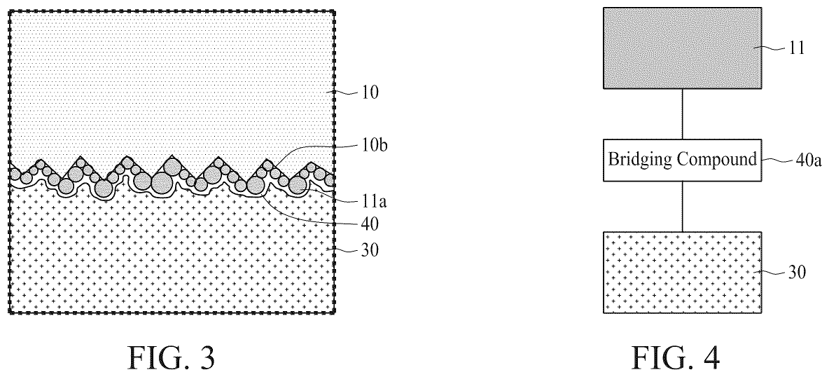

Please refer to FIG. 3, which shows an alternative embodiment in accordance with the enlarged view of the thermally conductive board 100 shown in FIG. 2. Compared with FIG. 2, a bridging layer 40 is added in FIG. 3. The thermally conductive board 100 may include the bridging layer 40 between the first metal coating layer 11 and the thermally conductive layer 30 in order to further enhance the adhesion strength between the first metal layer 10 and the thermally conductive layer 30. More specifically, after plating the first metal coating layer 11 on the first bottom surface 10b of the first metal layer 10, the bridging layer 40 may be coated on the first metal coating layer 11. The bridging layer 40 covers the bulges 11a of the first metal coating layer 11, by which interfacial activity between an inorganic material (e.g., the bulge 11a of the first metal coating layer 11) and an organic material (e.g., the thermally conductive layer 30) is chemically increased, and the adhesion strength therebetween can be further enhanced. FIG. 4 shows a schematic view of the bridging mechanism between the first metal coating layer 11 and the thermally conductive layer 30 offered by the bridging layer 40. The bridging layer 40 includes at least one bridging compound 40a selected from the group consisting of organic metal chelating agent, organic silane coupling agent, siloxane resin, epoxy resin, and any combination thereof. After hot pressing, the bridging layer 40 physically contacts the first metal coating layer 11 and the thermally conductive layer 30. In the meantime, the bridging compound 40a of the bridging layer 40 forms a chemical bond with the first metal coating layer 11, and forms another chemical bond with the thermally conductive layer 30. That is, the bridging compound 40a acts as a bridge between the first metal coating layer 11 and the thermally conductive layer 30. It is understood that the bridging compound 40a in FIG. 4 may be any compound selected from the above-said group, and thus the rectangular block shown in FIG. 4 and representing the bridging compound 40a is for illustrative purpose only. Different compounds may have different bonding structures or configurations, and the bond between two layers is shown as a straight line for illustrative purpose only. In an embodiment, the organic metal chelating agent may be organic aluminum salts, organic zirconium salts, or other organic metal salts. In an embodiment, the organic silane coupling agent may be acrylic silane coupling agent, amino silane coupling agent, or epoxy silane coupling agent. In addition, it is understood that the bridging compound 40a of the present invention is not limited to any one or combination described above, and any other resin, which is beneficial to connecting an inorganic interface to an organic interface, can be included in the scope of the present invention.

In order to further verify the performance of the thermally conductive board 100, many tests are performed and the experimental data is shown in Table 1 below.

TABLE 1

| | Thickness of | Thickness of | Rough- | | |
|---|---|---|---|---|---|
| | top nickel | bottom nickel | ness | Adhesion | |
| | coating layer | coating layer | Ra | strength | HHBT |
| Group | (μm) | (μm) | (μm) | (Kg/cm) | (hour) |
| C1 | 0 | 0 | <0.3 | 0.6 | <100 |
| C2 | 0 | 0 | 0.3 | <0.5 | <100 |
| E1 | 1 | 1 | 0.3 | 0.8 | 300 |
| E2 | 3 | 3 | 0.38 | 1 | 500 |
| E3 | 5 | 5 | 0.4 | 1.1 | 1000 |
| E4 | 10 | 10 | 0.52 | 1.4 | 3000 |
| E5 | 50 | 50 | 0.52 | 1.4 | 3000 |

As shown in Table 1, groups C1 and C2 represent comparative examples C1 and C2, and groups E1 to E5 represent embodiments E1 to E5 of the present invention. In each group, the size of the thermally conductive board 100 is “10 mm×10 mm” in top view; the first metal layer 10 and the second metal layer 20 are thick copper plates, each of which has a thickness of 0.3 mm; and the thermally conductive layer 30 has a thickness of 100 μm.

In the experiment, the thick copper plates in the embodiments E1 to E5 are plated with nickel coating layers. Therefore, a top nickel coating layer can be formed and corresponds to the first metal coating layer 11 shown in FIG. 1, and a bottom nickel coating layer can be formed and corresponds to the second metal coating layer 21 shown in FIG. 1. Before plating with nickel, the thick copper plates in the embodiments E1 to E5 are physically roughened to form coarse surfaces on the thick copper plates. As for comparative examples C1 and C2, both of which are also subject to the roughening treatment on the surfaces of the copper plates, although they are not plated with nickel. More specifically, the copper plates in the example C1 are chemically roughened by brown oxidation treatment, and the copper plates in the example C2 are physically roughened in the same way as the embodiments E1 to E5 do.

“Roughness Ra” refers to roughness average (Ra). It is the arithmetic average value of height deviations (along the Z axis) of a plate surface from a mean line, recorded within an evaluation length.

“Adhesion strength” is also called peel strength, the value of which is the force needed to separate the first metal layer 10 (or the second metal layer 20) from the thermally conductive layer 30.

“HHBT” refers to High Temperature High Humidity Bias Test. This test simulates an extreme condition of high temperature and high humidity, and assesses the device lifetime under such condition. A sample to be tested (i.e., the thermally conductive board 100) is applied with a DC (direct current) voltage of 1 kV in an environment at a temperature of 85° C. and relative humidity of 85%. The tested sample will be finally burnt out due to the applied DC voltage, and the hours of endurable time duration without burnout of sample can be used to assess the sample lifetime under extreme condition.

In Table 1, it is well observed that the thickness of the nickel coating layer affects the roughness Ra, adhesion strength, and HHBT. Along with the increase of the nickel coating layer's thickness from 1 μm (embodiment E1) to 50 μm (embodiment E5), the roughness Ra correspondingly increases from 0.3 μm to 0.52 μm, and the adhesion strength increases from 0.8 Kg/cm to 1.4 Kg/cm, which is larger than 0.8 Kg/cm as required by the Institute of Printed Circuit (IPC). As described above, besides the roughened surface (or coarse surface) of the copper plate, the nickel coating layer conformally coats on and further forms bulges on the roughened surface. Each bulge includes microstructure features with specific shape. Accordingly, the effect of mechanical interlocking at the interface can be significantly enhanced by combining the aforementioned three features (i.e., roughened surface, bulge, and microstructure feature). In addition, both the roughness Ra and adhesion strength in the embodiments E4 and E5 maintain at the same level, which shows that 10 μm of the thickness of the nickel coating layer is sufficient to obtain the best roughness Ra and adhesion strength. In comparison, although the copper plates in the examples C 1 and C2 are roughened, there are no nickel coating layers thereon; and therefore, the roughness Ra and adhesion strength are generally much lower. It is noted that the adhesion strength in the embodiment E1 is larger than that in the example C2, although both of them have the same roughness Ra. The reason for that is that each value of roughness Ra shows the roughness in an average way, that is, an average roughness of the entire surface. Therefore, the roughness Ra cannot precisely reflect partial surface morphology in a certain region, not to mention the microstructure features at micro-scale. The thickness of the nickel coating layer in the embodiment E1 is thinner than that in other embodiments, and thus the bulges of nickel coating layer in the embodiment E1 may cause height deviations merely in a certain region of surface while such height deviations are not large enough to be reflected on the average roughness (roughness Ra). However, it is clear that the bulges start to take effect and the roughened surface is more uneven when the thickness of the nickel coating layer is 1 μm. The effect of mechanical interlocking at the interface between the thermally conductive layer and the copper plate is significantly enhanced, thereby increasing the adhesion strength therebetween. Generally, the roughness Ra may range from 0.15 μm to 0.60 μm to give the same technical effect of mechanical interlocking described above as long as the nickel coating layer exists.

As for HHBT, the endurable time duration increases from 300 hours to 3000 hours along with the increase of the nickel coating layer's thickness from 1 μm (embodiment E1) to 50 μm (embodiment E5). The nickel coating layer has better chemical inertness, and acts as a barrier layer between the copper plate and the thermally conductive layer so as to prevent any undesired electrochemical reaction (e.g., copper ion migration) from happening. More specifically, the copper ions at the anode may migrate toward the cathode under the effect of an electric field, and this phenomenon may compromise the electrical insulation of the thermally conductive layer or even lead to short-circuit. Compared with copper, nickel has a lower Redox potential, and hence the nickel coating layer can provide an anti-oxidation property. Moreover, the copper plate is spaced apart from the thermally conductive layer at a distance because of the nickel coating layer. Technically, the nickel coating layer also provides a physical barrier besides its chemical inertness. From the above, the copper ion migration can be effectively prevented due to nickel coating on the surface of copper plate. In contrast, the examples C1 and C2 have shorter device lifetime without protection of the nickel coating layer, and the thermally conductive boards of them are burnt out in 100 hours under the applied voltage.

In addition, the adhesion strength is positively correlated with HHBT according to the result shown in Table 1. As described above, the adhesion strength is also called peel strength, which means that the larger the adhesion strength, the greater the resistance to peeling. A higher peel strength suggests that the thermally conductive board has better structural strength in its initial state. At the beginning of operation, the thermally conductive board experiences thermal expansion because of the generated heat. The thermal expansion may lead to deformation of the entire structure, thereby continuously exerting stress on the interface between the copper plate and thermally conductive layer. If the adhesion strength is too low, the copper plate is pulled away from the thermally conductive layer, and tiny holes (or gaps) are formed therebetween. These tiny holes (or gaps) at the interface compromise the integrity of the entire structure of the thermally conductive board, and the device lifetime is further affected due to that. However, the present invention increases the adhesion strength and chemical inertness, both of which are beneficial to the integrity of the entire structure of the thermally conductive board, and the reliability is enhanced. In other words, the operating endurance of the thermally conductive board (i.e., its service time or lifetime) can be significantly prolonged during practical use.

The above-described embodiments of the present invention are intended to be illustrative only. Numerous alternative embodiments may be devised by persons skilled in the art without departing from the scope of the following claims.

What is claimed is:

1. A thermally conductive board, comprising:
a first metal layer comprising copper, and having a first top surface and a first bottom surface opposite to the first top surface, wherein a first metal coating layer covers the first bottom surface;
a second metal layer comprising copper, and having a second top surface and a second bottom surface opposite to the second top surface, wherein a second metal coating layer covers the second top surface and faces the first metal coating layer; and
a thermally conductive layer being electrically insulative, and laminated between the first metal coating layer and the second metal coating layer.

2. The thermally conductive board of claim 1, wherein the first metal coating layer has a thickness not greater than 50 μm.

3. The thermally conductive board of claim 2, wherein the thickness of the first metal coating layer ranges from 1 μm to 10 μm.

4. The thermally conductive board of claim 3, wherein the second metal coating layer has a thickness ranging from 1 μm to 10 μm.

5. The thermally conductive board of claim 1, wherein the first bottom surface of the first metal layer is a coarse surface after physical roughening.

6. The thermally conductive board of claim 5, wherein the first metal coating layer forms a plurality of bulges on the coarse surface.

7. The thermally conductive board of claim 6, wherein each bulge of the first metal coating layer has a microstructure feature, and the microstructure feature is globular, polyhedral, needle-like, or irregularly shaped, thereby forming a surface morphology.

8. The thermally conductive board of claim 7, wherein the first metal coating layer has a roughness (Ra) ranging from 0.15 μm to 0.60 μm.

9. The thermally conductive board of claim 8, wherein an adhesion strength between the first metal layer and the thermally conductive layer ranges from 0.5 Kg/cm to 3.0 Kg/cm.

10. The thermally conductive board of claim 9, wherein the second top surface of the second metal layer is a coarse surface after physical roughening, and the second metal coating layer forms a plurality of bulges on the coarse surface, wherein the second metal coating layer has a roughness (Ra) ranging from 0.15 μm to 0.60 μm.

11. The thermally conductive board of claim 10, wherein each bulge of the second metal coating layer has a microstructure feature, and the microstructure feature is globular, polyhedral, needle-like, or irregularly shaped, thereby forming a surface morphology.

12. The thermally conductive board of claim 11, wherein an adhesion strength between the second metal layer and the thermally conductive layer ranges from 0.5 Kg/cm to 3.0 Kg/cm.

13. The thermally conductive board of claim 1, wherein the first metal coating layer and the second metal coating layer are each independently made of a material selected from the group consisting of nickel, tin, zinc, chromium, bismuth, cobalt, and any combination thereof.

14. The thermally conductive board of claim 1, further comprising a bridging layer laminated between the first metal coating layer and the thermally conductive layer.

15. The thermally conductive board of claim 14, wherein the bridging layer comprises at least one bridging compound selected from the group consisting of organic metal chelating agent, organic silane coupling agent, siloxane resin, epoxy resin, and any combination thereof.

16. The thermally conductive board of claim 1, wherein the first metal layer and the second metal layer are made of copper.

17. The thermally conductive board of claim 1, wherein the first metal layer has a thickness ranging from 0.1 mm to 10 mm.

18. The thermally conductive board of claim 1, wherein the thermally conductive layer comprises a polymer matrix and a heat conductive filler, and the heat conductive filler has a heat conductivity ranging from 3 W/mK to 20 W/mK.

19. The thermally conductive board of claim 18, wherein the polymer matrix has a thermoset resin, and the heat conductive filler has a thermally conductive ceramic material selected from the group consisting of zirconium nitride, boron nitride, aluminum nitride, silicon nitride, aluminum oxide, magnesium oxide, zinc oxide, silicon dioxide, titanium dioxide, and any combination thereof.
